(19) United States
(12) Patent Application Publication
(10) Pub. No.: US 2024/0368758 A1
(43) Pub. Date: Nov. 7, 2024

(54) DEVICE AND METHOD FOR DISPENSING A GAS PHASE OF A SOLID PRECURSOR

(71) Applicant: AIR LIQUIDE ELECTRONICS SYSTEMS, Paris (FR)

(72) Inventors: Sonia PLAZA, Echirolles (FR); Vanina TODOROVA, Echirolles (FR); Herve DULPHY, Echirolles (FR); Valere LAURENT, Echirolles (FR)

(73) Assignee: AIR LIQUIDE ELECTRONICS SYSTEMS, Paris (FR)

(21) Appl. No.: 18/567,897

(22) PCT Filed: Apr. 15, 2022
(86) PCT No.: PCT/EP2022/060165

§ 371 Date: Dec. 7, 2023

(30) Foreign Application Priority Data
Jun. 7, 2021 (FR) FR2105994

(51) Int. Cl. C23C 16/448; C23C 16/455

(52) U.S. Cl. CPC C23C 16/4481; C23C 16/45557; C23C 16/45561

(57) ABSTRACT

Disclosed is a device for dispensing a gas phase of at least one solid precursor, said device comprising a container intended to contain a solid phase of said precursor, a first heating means configured to heat at least one part of the container and/or of the solid phase so as to form a gas phase of said precursor in the container, and dispensing means fluidically connected to the container and configured to dispense the gas phase from the container to a point of use. According to the invention, the device comprises a chamber which has an internal volume within which are the container and said dispensing means, said device also comprising a second heating means configured to heat at least one part of the internal volume of the chamber.

### CROSS-REFERENCE TO RELATED APPLICATIONS

This application is a § 371 of International PCT Application PCT/EP2022/060165, filed Apr. 15, 2022, which claims § 119(a) foreign priority to French patent application FR 2 105 994, filed Jun. 7, 2021.

### FIELD OF THE INVENTION

The present invention relates to a device for distributing a gas phase of a solid precursor, said gas phase being intended to be used in a treatment installation. The invention also relates to a method for distributing a gas phase of a solid precursor using such a device and to a treatment installation comprising said device.

### BACKGROUND

The invention can be applied to the distribution of precursors in various treatment methods such as the etching or cleaning of substrates, the deposition of coatings or thin layers. The invention notably finds application in the semiconductor industry, the precursor possibly for example being involved in the production of thin layers or the doping of substrates during the manufacture of electronic components or integrated circuits.

In particular, the device according to the invention is intended to provide a gas phase of a precursor to a chemical vapor deposition installation. The precursor may be distributed in pure form or diluted in a carrier gas.

During a chemical vapor deposition process, a substrate is exposed to one or more precursors in the gas phase, which react and/or decompose on the surface of the substrate so as to generate the desired deposit.

Numerous materials are liable to be used as precursors in treatment installations of the chemical vapor deposition type. These precursors may be in the gas, liquid or solid state. These three fundamental states are generally considered under standard pressure and temperature conditions.

The gaseous precursors are the easiest to transport to their point of use. Specifically, they are generally stored under pressure in their container and thus flow naturally to a point of use at lower pressure.

The distribution of precursors in the liquid state imposes greater constraints. One distribution method consists in withdrawing the liquid phase of the precursor from its container by injecting an immiscible inert gas therein which will push the liquid into an immersed tube. Another method is based on a heating of the liquid phase to vaporize it, the pressure and the temperature of the vapor phase having to be maintained up to the point of use.

Lots of precursors that exhibit advantageous properties, in particular for the semiconductor industry, are available only in the solid state under standard pressure and temperature conditions. These precursors may be in the form of pellets or powder. However, they generally have a very high sublimation temperature and a very low saturation vapor pressure at ambient temperature, and are therefore not able to be distributed directly to the treatment installation, due to the low quantity of gas that would be provided.

### RELATED ART

Various solutions have been proposed in order to be able to use these solid precursors on an industrial scale. A distribution device based on the sublimation, that is to say passage from the solid state to the gaseous state, of a solid precursor is notably known from document EP-A-2247769. The precursor is placed in a vessel which is heated to a temperature enabling sublimation of the solid precursor and the generation of vapors of said precursor. A carrier gas flows through the heated precursor in the vessel and re-emerges therefrom saturated with vapors of the solid precursor in order to be distributed to the point of use.

Depending on the requirements of the treatment installation, the current solutions can prove to be insufficient.

Specifically, to ensure the reliability and the reproducibility of the treatment methods performed with the solid precursor for the user, it is necessary for the precursor to be sublimed at the desired temperature and the vapor phase of the precursor to be provided to the point of use in the saturated state and at the desired pressure, without any contamination. There is also a need in terms of operational flexibility, since the flow rate distributed to the point of use may vary depending on the needs of the installation and the treatment method carried out, and since the numerous solid precursors available each have different sublimation temperatures and pressures.

Furthermore, when a carrier gas is used to transport the precursor vapors to the point of use, the concentration of precursor in the carrier gas can be difficult to control over time. Specifically, when the solid precursor is sublimed, the form, the morphology, the contact surface with the carrier gas and the volume of solid precursor change, thus modifying the vapor flow rate and therefore the concentration of precursor in the carrier gas. It is all the more difficult to maintain a constant concentration of precursor in the carrier gas when the metrology enabling quantification is difficult to develop. In order to be able to maintain a constant precursor concentration, it is necessary for the carrier gas to be saturated with precursor throughout the use of the vessel. Certain vessels have a particular design making it possible to achieve the saturation of the carrier gas. When the vessel used has a design that does not make it possible to achieve the saturation of the carrier gas with precursor for the entire period of use of the vessel, the proportion of precursor in the carrier gas progressively decreases as the vessel is used.

Moreover, the control of the temperature of the sublimed precursor can pose difficulties. Specifically, the gas phase of the precursor has to be kept at a temperature greater than or equal to the sublimation temperature over the entire path from the vessel to the point of use. The presence of colder points on the fluid path downstream of the vessel may result in crystallization, i.e. condensation, of the gas phase at these points. This results in a variation in the flow rate of precursor distributed, and also clogging of components of the gas distribution circuit, such as the valves, the flow rate controllers, etc., and passage restrictions in the pipes, thus causing additional flow rate variations and malfunctions of the installation.

### SUMMARY OF THE INVENTION

The aim of the invention is to overcome all or some of the drawbacks mentioned above, notably by proposing a device for distributing a gas phase of a solid precursor which allows a stable and flexible distribution, as a function notably of the flow rates required at the point of use of the precursor and/or the nature of the precursor, independently of the design of the vessel containing the precursor, and with which the risk of condensation of the gas phase during its conveyance to the point of use is greatly reduced, or even eliminated, but without excessive complexification of the device.

To this end, the solution of the invention is a device for distributing a gas phase of at least one solid precursor, said device comprising:
a vessel intended to contain a solid phase of said precursor, the vessel having a bottom and a top,
a first heating means configured to heat at least a part of the vessel and/or of the solid phase so as to form a gas phase of said precursor in the vessel,
distribution means fluidically connected to the vessel and configured to distribute the gas phase from the vessel to a point of use,
   the device further comprising an enclosure having an internal volume in which the vessel, the first heating means and the distribution means are arranged, the enclosure having a substantially vertical axial direction oriented in an upward direction, the internal volume of the enclosure comprising a lower zone and an upper zone, the device further comprising a second heating means configured to heat at least a part of the internal volume of the enclosure, the second heating means comprising an air circulation means configured to circulate air from the second heating means in the direction of the internal volume of the enclosure.

Such an arrangement for the second heating means makes it possible to ensure a homogeneous temperature within the enclosure by maintaining a temperature gradient within this enclosure. This makes it possible to avoid condensation of the gas phase during its transport to the point of use.

Depending on the case, the invention may comprise one or more of the features outlined below.

The second heating means is configured to heat at least a part of the internal volume of the enclosure by forced convection.

The second heating means is separate from the first heating means.

The second heating means is configured to heat at least half of the internal volume of the enclosure, notably substantially the entire internal volume of the enclosure.

The second heating means is configured to generate a temperature profile within the vessel and distribution means, said temperature profile having temperatures which increase in the axial direction.

The upper zone is arranged at a higher level than that of the lower zone in the axial direction, the first vessel and the first heating means being arranged in the lower zone and the second heating means and the distribution means being arranged in the upper zone.

The air circulation means is arranged in the upper zone.

The air circulation means comprises at least one fan, a blower, a nozzle or a turbine.

The top is arranged at a higher level than that of the bottom in the axial direction.

The temperature profile comprises a first temperature at the distribution means and a second temperature at the top of the vessel, the first temperature being greater than the second temperature.

The second heating means is configured such that the temperature profile has a second temperature at the top of the vessel and a third temperature at the bottom of the vessel, the second temperature being greater than the third temperature.

The device comprises a third heating means arranged in the lower zone of the enclosure, preferably around at least a part of the bottom of the vessel or under the bottom of the vessel.

The third heating means is configured to modify and/or adjust the temperature profile, in particular to increase at least the third temperature.

The second heating means and/or the third heating means are/is configured such that the difference between the first temperature and the second temperature is from 1 to 35° C., in particular from 1 to 10° C., and/or the difference between the second temperature and the third temperature is from 2 to 70° C., in particular from 2 to 20° C.

The second heating means comprises at least one electrical resistor notably mounted on a wall of the enclosure or in the vicinity of said wall.

The third heating means comprises a heating plate on which the vessel rests.

The device comprises at least one pressure sensor configured to measure the pressure inside the vessel, and a control unit connected to the pressure sensor and to the first heating means, the control unit notably being configured to regulate and/or adjust the heating power delivered by the first heating means as a function of the pressure measured by the pressure sensor.

The control unit comprises means for comparing the pressure in the vessel with a predetermined setpoint pressure, the control unit being configured to reduce the heating power, notably delivered by the first heating means, when the pressure measured inside the vessel is greater than or equal to the setpoint pressure and to increase the heating power, notably delivered by the first heating means, when the pressure in the vessel is lower than the predetermined setpoint pressure.

The control unit is configured to regulate and/or adjust the heating power delivered by the second heating means according to a first predetermined temperature setpoint and/or the control unit is configured to regulate and/or adjust the heating power delivered by the third heating means according to a second predetermined temperature setpoint.

The device comprises a source of carrier gas, a supply duct fluidically connecting the source of carrier gas to an inlet of the vessel and means for circulating the carrier gas in the vessel, said means for circulating the carrier gas being configured to circulate the carrier gas between the inlet and an outlet of the vessel such that the distribution means distribute a gas mixture comprising the gas phase and the carrier gas from the vessel, said means for circulating the carrier gas notably being configured to control the flow rate of carrier gas circulating in the vessel and/or to control the pressure in the vessel.

The first heating means is configured to deliver a variable heating power.

The device comprises at least one temperature sensor configured to measure the temperature of an outer surface of the vessel and/or to measure the temperature inside the enclosure, and a control unit connected to the temperature sensor and to the first heating means, the control unit notably being configured to vary the heating power delivered by the first heating means as a function of the temperature measured by the temperature sensor.

The temperature sensor is disposed on the outer wall of the vessel or in the vessel.

The control unit comprises means for comparing the temperature measured by the temperature sensor with a third temperature setpoint, the control unit being configured to reduce the heating power when the temperature measured is greater than the third temperature setpoint and to increase the heating power when the temperature measured is lower than the third temperature setpoint.

The distribution means comprise at least one distribution duct passing through a first wall of the enclosure, a heating element forming a sleeve around at least a part of the distribution duct and extending on either side of said first wall.

The sleeve comprises at least two shells or a cylinder.

The sleeve comprises a conducting material such as aluminium.

The sleeve is configured to conform to the distribution duct at the first wall.

The sleeve comprises at least one heating resistor and at least one temperature probe, the assembly notably being arranged such that the heating power of the heating resistor of the sleeve is controlled on the basis of the temperature probe of the sleeve.

Such an arrangement makes it possible to heat the distribution duct in the vicinity of the first wall so as to avoid a cold point.

The sleeve is separate from the first heating means and from the second heating means.

Furthermore, the invention relates to a distribution assembly comprising at least two distribution devices as defined above, each device comprising an enclosure, a vessel and respective distribution means fluidically connected to a common pipe, said assembly comprising switching means configured to occupy a first position in which the gas phase is distributed into the common pipe from one of the two vessels and, when the quantity of precursor in the vessel is lower than or equal to a predetermined low threshold, to occupy a second position in which the gas phase is distributed into the common pipe from the other of the two vessels or to occupy an intermediate position in which the gas phase is distributed from both vessels simultaneously, the switching means being connected to a member for measuring a physical quantity representative of the quantity of precursor in the vessel, selected from among: the mass of the vessel, the pressure in the vessel, the temperature of an outer surface of the vessel, the movement of the switching means from the first position to the second position being determined as a function of the measurement of said physical quantity.

The features above can be applied individually or in combination to this aspect of the invention.

According to another aspect, the invention relates to a treatment installation, in particular a chemical vapor deposition installation, comprising a treatment chamber in which one or more substrates to be treated are installed, the treatment chamber comprising means for introducing at least one gas phase of a solid precursor into the treatment chamber, characterized in that the introduction means are fluidically connected to the distribution means of a device or of an assembly as defined above.

The features above can be applied individually or in combination to this aspect of the invention.

Furthermore, the invention relates to a method for distributing a gas phase of at least one solid precursor, comprising the following steps:
a) arranging a solid phase of said precursor in a vessel,
b) heating at least a part of the vessel and/or of the solid phase with a first heating means so as to form a gas phase of said precursor in the vessel,
c) distributing the gas phase from the vessel by way of distribution means that are fluidically connected to the vessel, characterized in that said method further comprises the steps of:
d) arranging the vessel, the first heating means and the distribution means in an internal volume of an enclosure, the enclosure having a substantially vertical axial direction oriented in an upward direction, the internal volume of the enclosure comprising a lower zone and an upper zone,
e) heating at least a part of the internal volume of the enclosure with a second heating means, the second heating means comprising an air circulation means configured to circulate air from the second heating means in the direction of the internal volume of the enclosure.

The features above can be applied individually or in combination to this aspect of the invention.

Depending on the case, this aspect of the invention may comprise one or more of the features outlined below.

The second heating means is configured to generate a temperature profile within the vessel and distribution means, said temperature profile having temperatures which increase in the axial direction.

The temperature profile comprises a first temperature at the distribution means and a second temperature at the top of the vessel, the first temperature being greater than the second temperature.

The second heating means is configured such that the temperature profile has a second temperature at the top of the vessel and a third temperature at the bottom of the vessel, the second temperature being greater than the third temperature.

The method comprises the step of modifying and/or adjusting the temperature profile, in particular so as to increase at least the third temperature, with a third heating means arranged in the lower zone of the enclosure, preferably around at least a part of the bottom of the vessel or under the bottom of the vessel.

The second heating means and/or the third heating means are/is configured such that the difference between the first temperature and the second temperature is from 1 to 35° C., in particular from 1 to 10° C., and/or the difference between the second temperature and the third temperature is from 2 to 70° C., in particular from 2 to 20° C.

The method comprises the step of reducing the heating power, notably delivered by the first heating means, when the pressure measured inside the vessel is greater than or equal to the setpoint pressure and to increase the heating power, notably delivered by the first heating means, when the pressure in the vessel is lower than the predetermined setpoint pressure, the control unit comprising means for comparing the pressure in the vessel, notably as measured by the pressure sensor, with a predetermined setpoint pressure.

The method comprises the step of regulating and/or adjusting the heating power delivered by the third heating means according to a predetermined second temperature setpoint, the regulation and/or adjustment notably being implemented by the control unit.

The method comprises the step of regulating and/or adjusting the heating power delivered by the second heating means according to a predetermined first temperature setpoint, the regulation and/or adjustment notably being implemented by the control unit.

The control unit comprises means for comparing the temperature measured by the temperature sensor with a third temperature setpoint, the control unit being configured to reduce the heating power when the temperature measured is greater than the third temperature setpoint and to increase the heating power when the temperature measured is lower than the third temperature setpoint.

### BRIEF DESCRIPTION OF THE FIGURES

The invention will now be better understood by virtue of the following detailed description, which is given by way of non-limiting illustration, with reference to the appended figures described below.

FIG. 1 schematically shows a distribution device according to one embodiment of the invention.

FIG. 2 schematically shows a distribution device according to another embodiment of the invention.

FIG. 3 schematically shows a distribution device according to another embodiment of the invention.

FIG. 4 shows examples of temperature distribution in a distribution device according to one embodiment of the invention.

FIG. 5 schematically shows a distribution device according to another embodiment of the invention.

FIG. 6 schematically shows a distribution device according to another embodiment of the invention.

FIG. 7 schematically shows a distribution assembly according to one embodiment of the invention.

FIG. 8 shows an example of the change over time of the flow rate and of the pressure of a precursor distributed in pure form by a device according to one embodiment of the invention.

### DETAILED DESCRIPTION OF THE INVENTION

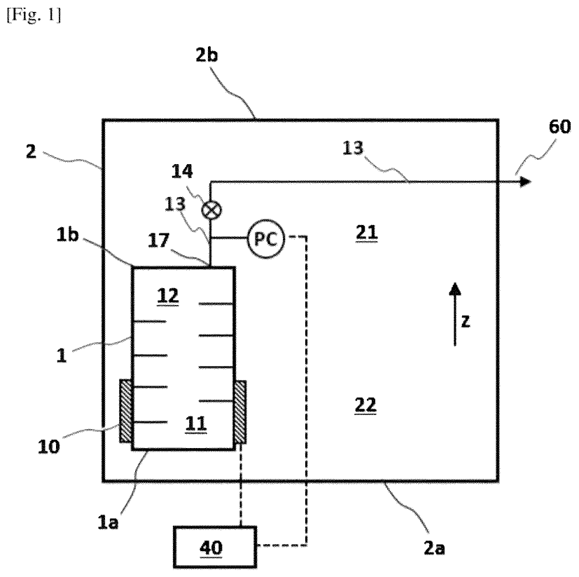

FIG. 1 shows a device according to one embodiment of the invention in which the gas phase of the precursor is distributed in pure form.

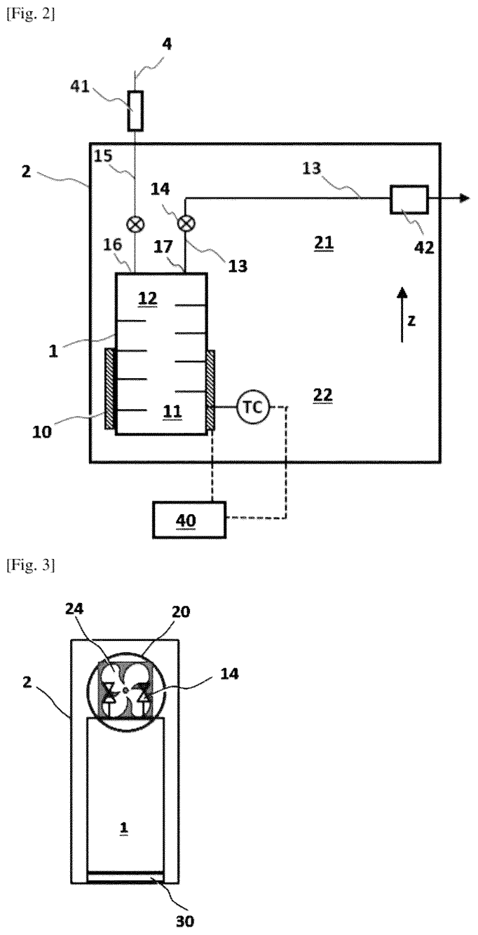

According to another possibility illustrated in FIG. 2, a device according to the invention may also be configured to distribute the gas phase of the precursor in a form diluted in a carrier gas.

The term “precursor” is understood to mean a chemical element or compound capable of and suitable for initiating a chemical reaction in order to be transformed. In particular, in the case of a precursor intended to carry out chemical vapor deposition, said precursor is configured to react and/or decompose on the surface of a substrate so as to generate the desired deposit thereon.

The solid precursor may comprise any inorganic or organic chemical compound based on at least one of the following: aluminum, barium, bismuth, chromium, cobalt, copper, gold, hafnium, indium, iridium, iron, lanthanum, lead, magnesium, molybdenum, nickel, niobium, platinum, ruthenium, silver, strontium, tantalum, titanium, tungsten, yttrium, zirconium. For example, precursors such as MoCl₅, MoO₂Cl₂, Mo(CO)₆, W(CO)₆, WCl₆, WCl₅, HfCl₄ may be distributed.

The term “carrier gas” is understood to mean a gas capable of and suitable for transporting the gas phase of the solid precursor to its point of use, preferably a gas formed of one or more inert pure substances such as hydrogen (H2), nitrogen (N2), argon (Ar) or helium (He).

The device according to the invention aims to distribute vapors of a precursor to a point of use 60, which is capable of being and intended to be connected to a treatment installation that uses said precursor. Note that the term “treatment installation” may extend both to a single treatment entity and to several entities supplied in parallel by the gas phase of the solid precursor, notably several entities arranged downstream of a branch box.

As can be seen in FIG. 1, the distribution device comprises a vessel 1 containing a solid phase 11 of the precursor. The vessel 1 has a bottom 1a, a top 1b and a peripheral wall which extends from the bottom to the top. The peripheral wall may be of cylindrical overall shape. The precursor in the solid state may be in the form of pellets or powder. The saturation vapor pressure of a solid precursor at ambient temperature is generally low, the quantity of gas phase 12 of the solid precursor that is contained in the vessel 1 and that can be withdrawn is therefore low.

In order to increase the flow rate of vapor phase distributed from the vessel 1, a first heating means 10 is arranged in the region of the vessel 1 so as to heat at least a part of the vessel 1 and/or of the solid phase 11. This makes it possible to heat at least a part of the solid precursor in the vessel 1 and to increase the saturation vapor pressure of the precursor. This increases the quantity of sublimable precursor in the vessel 1 and therefore the quantity of gas phase 12 that can be distributed from the vessel 1.

When the gas phase 12 is withdrawn from the vessel 1, part of the solid phase 11 has to be sublimed so as to regenerate the gas phase 12 as it is used in order to maintain the equilibrium in the vessel 1. The heating of the vessel 1 makes it possible to compensate for pressure drops caused by the removal of the gas phase 12 from the vessel 1 and to supply the energy necessary to compensate for the drop in temperature of the solid precursor in order to sublime it.

Preferably, the first heating means 10 are external to the vessels. It is also conceivable for the first heating means 10 to be internal to the vessel.

According to one embodiment, the first heating means 10 is disposed around all or part of the vessel 1 and extends over all or some of the height of the vessel 1, preferably at least at the lower part of the vessel. This makes it possible to first and foremost heat the solid phase which is preferably also situated in the lower part. Note that the lower part is preferably understood to mean a part extending from the bottom 1a over a height representing up to 50%, in particular up to 30%, more particularly up to 20%, of the total height of the vessel 1.

Note that the first heating means may be configured to heat at least a part of the outer surface of the vessel 1 and/or at least a part of any internal components of the vessel 1, notably internal components that may act as supports for the solid phase 11. The transfer of heat to the solid phase 11 preferably takes place by thermal conduction between the heated surface and the solid phase 11.

The first heating means 10 may be in the form of at least one heating cord or of at least one heating belt or potentially of a shell for circulation of heat transfer fluid. Depending on the case, the first heating means 10 may be of the inductive or resistive type. For example, the body of the vessel 1 may be heated with the aid of at least one resistive conducting element in which the passage of an electrical current produces heat. According to another advantageous possibility, the first heating means 10 comprises magnetic induction means capable of creating a magnetic field in at least a part of the envelope of the vessel 1 and of heating the material of the vessel 1 by virtue of the induced electrical current.

Distribution means 13, 14 are fluidically connected to the vessel 1 so as to distribute the gas phase 12 from the vessel 1 in the direction of the point of use 60. The distribution means may comprise at least one portion of a distribution duct 13, of which one end is connected to an outlet 17 of the vessel 1 and another end is connected to the point of use 60. The distribution means may comprise at least one valve 14 arranged on the path of the gas phase 12 downstream of the outlet 17. Preferably, said valve 14 is mounted on the duct 13.

According to the invention, the device further comprises an enclosure 2 having an internal volume in which the vessel 1 and the distribution means 13, 14 are arranged. As can be seen in FIG. 3, said device further comprises a second heating means 20 configured to heat at least a part of the internal volume of the enclosure 2. In particular, the enclosure 2 and the second heating means 20 form part of an apparatus of the oven or furnace type. Advantageously, the transfer of heat takes place by thermal convection from the heated atmosphere of the internal volume to the vessel 1 and the distribution means 13, 14. In particular, the transfer of heat takes place by forced convection.

The second heating means 20 thus heats both the vessel 1 and the distribution means 13, 14 situated in the same internal volume. The use of a heated enclosure 2 makes it possible to more effectively control the temperature of the sublimed precursor, simultaneously in the vessel 1 and downstream of the vessel 1. The gas phase of the precursor can be kept at a temperature greater than or equal to the sublimation temperature over its entire path from the vessel 1. The presence of colder points on the fluid path downstream of the vessel can thus be avoided, thus avoiding the risk of crystallization of the precursor. Even the top of the vessel 1, which could not be heated sufficiently by the first heating means 10, can be heated in the enclosure 2. The arrangement of the main components of the distribution device in one and the same volume makes it possible to regulate the temperature more effectively and more simply than if the components were to be heated by independent heating systems.

Furthermore, the second heating means 20 heats the vessel 1 and contributes to the increase in the vapor pressure of the solid precursor. The first heating means 10 and the second heating means 20 therefore act in synergy to supply the heat necessary in order for the desired pressure to be reached and for the desired precursor flow rate to be ensured.

FIG. 1 shows an enclosure 2 having a lower wall 2a and an upper wall 2b with an axial direction z which is substantially vertical and oriented in an upward direction, from the lower wall 2a to the upper wall 2b. Advantageously, the second heating means 20 is configured such that the temperature of the vessel 1 and of the distribution means 13, 14 situated in the internal volume of the enclosure 2 increases in the axial direction z. In other words, the second heating means 20 is configured to generate, within the vessel 1 and distribution means 13, 14, a temperature profile having temperatures which increase in the axial direction z.

The distribution means 13, 14 are arranged above the vessel 1 in the axial direction z. The distribution means 13, 14 are thus situated in a region of the enclosure in which the temperatures are higher than at the vessel 1. The gas phase circulating through the distribution means 13, 14 is thus heated to a temperature greater than the temperature to which the precursor is heated in the vessel 1. This makes it possible to have a higher temperature downstream of the sublimation site and thus to avoid condensation of the gas phase during its transport to the point of use. In a heated enclosure, in particular in an apparatus of the furnace or oven type, advantage is also taken of the fact that the temperatures naturally tend to increase in an upward direction, the air contained in said enclosure being even less dense as its temperature increases.

The temperature profile is understood to mean a spatial distribution of temperatures as a function of a given level in the axial direction z. The temperatures of the profile are preferably determined in relation to a material that makes up the vessel or the distribution means, in particular on the outer surface of these elements. It is also conceivable for the temperatures to be determined in relation to a fluid contained in the vessel or in the distribution means. Note that the temperatures of the profile are not necessarily determined along the same axis parallel to the axial direction z, but they may be determined at different locations in the internal volume, the variable to be considered being the level of the measurement point in the internal volume with respect to the axial direction z.

Preferably, the temperature profile exhibits a linear increase in temperature. Note that a temperature profile with an increase by stages and several zones at different temperature levels is also conceivable.

In particular, the second heating means 20 can be configured to generate, within the vessel 1 and the distribution means 13, 14, a thermal gradient in the axial direction z, in particular a thermal gradient of at least 0.05° C./cm, preferably a thermal gradient of between 0.05 and 10° C./cm.

Note that, more generally, the second heating means can be configured to generate, in the internal volume of the enclosure 2, an increase in the temperature in the axial direction z.

According to one embodiment, the enclosure 2 has at least an upper zone 21 in which the distribution means 13, 14 are arranged and a lower zone 22 in which the vessel 1 is arranged. The upper zone 21 is arranged above the lower zone 22 in the axial direction z. The second heating means 20 is configured such that the upper zone 21 has a temperature or temperatures greater than the temperature or temperatures in the lower zone 22.

Preferably, the vessel 1 comprises a bottom 1a and a top 1b, the top 1b being arranged at a higher level than that of the bottom 1a in the axial direction z. The second heating means 20 is configured such that a first temperature determined at the distribution means 13, 14 is greater than a second temperature determined at the top 1b.

Preferably, the delimitation between the lower zone 22 and the upper zone 21 is situated at or in the vicinity of the top 1b of the vessel 1.

Advantageously, the second heating means 20 is configured such that the temperature profile has a second temperature at the top 1b and a third temperature at the bottom 1a. The second temperature is greater than the third temperature. This control of the distribution of the temperature in the vessel 1 makes it possible to avoid recrystallization of the precursor vapors in the upper part of the vessel, where they would be difficult to re-sublime and could lead to clogging. This distribution promotes the recrystallization of the vapors in the lower part of the vessel.

In particular, the second heating means 20 may be configured such that the vessel 1 and the distribution means 13, 14 have several temperature levels along the axial direction z, selected from among:
a first temperature measured at the distribution means 13, 14, preferably at a height of between 25 and 100 cm above the top of the vessel 1,
a second temperature measured at the top of the vessel 1,
a third temperature measured at the bottom of the vessel 1,
a fourth temperature measured at an intermediate level between the bottom and the top of the vessel 1, preferably at a distance of between 20 and 40 cm from the bottom of the vessel 1.

Preferably, the difference between the first temperature and the second temperature is between 1 and 35° C., preferably between 1 and 10° C. Preferably, the difference between the first temperature and the third temperature is between 3 and 30° C. Preferably, the difference between the first temperature and the fourth temperature is between 2 and 70° C., preferably between 2 and 20° C. Preferably, the difference between the first temperature and the fourth temperature is between 2 and 70° C., preferably between 2 and 20° C.

Since the passage cross section of the pipe at the outlet of the vessel is smaller than the cross section of the vessel, it is advantageous to keep the distribution means 13 and 14 at a temperature greater than the temperature of the top of the vessel 1, in order to avoid the crystallization of the precursor in the pipes 13 or in the valves 14 downstream of the vessel 1.

According to embodiment possibilities, the vessel 1 has a first height of between 20 and 100 cm and/or the enclosure 2 has a second height of between 30 and 150 cm. The first height is measured inside the vessel 1, between the top and the bottom and parallel to the axial direction z. The second height is measured inside the enclosure, between the lower wall and the upper wall and parallel to the axial direction z.

Preferably, the solid precursor is arranged in the lower part of the vessel 1. According to one embodiment, the solid precursor is arranged in the vessel 1 at a height of between 0 and 90 cm, said height being measured from the bottom of the vessel 1.

As can be seen in FIG. 3, the second heating means 20 may comprise at least one electrical resistor, arranged at a high level of the enclosure, preferably in the zone in which the distribution means 13, 14 are arranged. Preferably, the second means 20 is disposed in or on a lateral wall of the enclosure 2.

Preferably, the second heating means 20 is associated with an air circulation means 24 configured to circulate air from the second heating means 20 in the direction of the internal volume of the enclosure 2. In particular, the circulation means 24 may comprise at least one fan. Preferably, the air circulation means 24 is configured to recover cold air from inside the enclosure, preferably from a central region of the enclosure, so that it is heated by the second heating means 20, and to eject the heated air into the internal volume, preferably via the sides. The air can circulate within the oven in a closed circuit, notably the circulated air is heated, circulates in the enclosure and then is drawn in by the circulation means so as to again be directed to the second heating means 20.

Optionally, the enclosure may also comprise means for supplying outside air to the enclosure, such as at least one opening arranged in the vicinity of the circulation means 24, and air discharge means connected to the outside of the enclosure. These means for discharging the hot air from the enclosure can be used to cool the enclosure more rapidly if required or to extract the air from the enclosure in the event of a problem, such as a leak.

Advantageously, the second heating means 20 is connected to a control member that makes it possible to adjust the heating power so as to adjust the heating temperature of the vessel 1. It is thus possible to adjust and/or modify the temperature profile of the vessel 1 and of the distribution means 13, 14. Preferably, the control member is configured to regulate and/or adjust the heating power delivered by the second heating means 20 according to a first temperature setpoint of a predetermined value. Once the predetermined value has been selected, the regulation is effected to a constant temperature setpoint. The temperature maintenance can be effected by comparison of a temperature measured at the second means 20 with the first setpoint and regulation in a closed loop.

Advantageously, the device according to the invention further comprises a third heating means 30 arranged in the enclosure 2. Preferably, the third heating means 30 is arranged, in the direction z, at a lower level than the level of the second heating means in the enclosure 2.

Preferably, the third heating means 30 is arranged in the lower zone 22 of the enclosure 2, preferably at the lower part of the vessel 1, and advantageously at the bottom of the vessel 1 or under the vessel 1.

According to one possibility, the third heating means 30 comprises a heating plate arranged under the vessel 1, in particular a plate formed of a thermally conducting material such as aluminum provided with at least one electrical resistor which heats the plate. The third heating means 30 is configured to heat at least a part of the vessel 1, preferably by thermal conduction. The supply of heat preferably takes place at the bottom of the vessel 1. The heat diffuses by conduction into the walls of the vessel 1, from the bottom to the top.

Advantageously, the third heating means 30 is connected to a control member that makes it possible to adjust the heating power so as to adjust the heating temperature of the vessel 1. The temperature differential exhibited by the vessel 1 in the axial direction z is thus adjusted. Preferably, the control member is configured to regulate and/or adjust the heating power delivered by the third heating means 30 according to a second temperature setpoint of a predetermined value. Once the predetermined value has been selected, the regulation is effected to a constant temperature setpoint. The temperature maintenance can be effected by comparison of a temperature measured at the third means 30 with the setpoint and regulation in a closed loop.

The third heating means 30 makes it possible to supply additional heat in addition to the second heating means 20, in order to more easily sublime the solid precursor. This provides an additional degree of freedom for the adjustments of the temperature difference between the top and the bottom of the vessel and of the temperature difference between the bottom of the vessel 1 and the distribution means 13, 14. It is thus possible to adapt the profile of temperatures to the sublimation conditions in the device, notably nature of the precursor, pressure and/or distribution flow rate, etc.

In particular, the control unit makes it possible to adjust the temperature to which the bottom of the vessel 1 is heated. Thus, by increasing the second setpoint, this increases the power of the third heating means, the temperature of the bottom of the vessel 1 can be increased and the temperature differences between the top and the bottom of the vessel and between the bottom of the vessel 1 and the distribution means 13, 14 can be reduced. Conversely, a decrease in the second temperature setpoint causes a decrease in the power of the third heating means and can make it possible to increase the temperature differences. Note that the device may be configured to allow a relative adjustment of the powers delivered by the third heating means and the second heating means.

According to a particular embodiment, the second heating means is configured such that the difference between the first temperature and the second temperature is between 1 and 35° C. when only the second heating means and the first heating means are in operation. The second heating means and the third heating means may be configured such that the difference between the first temperature and the second temperature is between 1 and 10° C. when the second heating means, the first heating means and the third means are in operation.

As an alternative or in addition, the second heating means may be configured such that the difference between the first temperature and the third temperature is between 2 and 70° C. when only the second heating means and the first heating means are in operation. The second heating means and the third heating means may be configured such that the difference between the first temperature and the third temperature is between 2 and 20° C. when the second heating means, the first heating means and the third means are in operation.

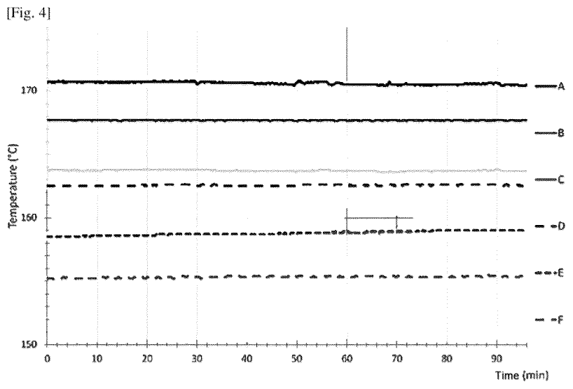

FIG. 4 illustrates examples of temperature distribution in an enclosure of a distribution according to one embodiment of the invention. The vessel 1 has a first height of 49 cm. The enclosure 2 has a second height of 135 cm. The second heating means 20 heats the upper zone 21 of the enclosure and, to a lesser extent, the lower zone 22 of the enclosure. The third heating means 30 heats the bottom of the vessel 1. Part of the heat disperses toward the top of the vessel by thermal conduction. The curves show the change over time of temperatures at different levels on the vessel 1 and on the distribution means 13 and 14 along the axial direction z.

Curve A corresponds to a temperature measurement at a distribution means 13 arranged at a distance of the order of 60 cm above the top of the vessel 1. Curve B corresponds to a temperature measurement at a valve 14 arranged at a distance of the order of 13 cm above the top of the vessel 1. Curve C corresponds to a temperature measurement at the top of the vessel 1. Curve D corresponds to a temperature measurement at the mid-height of the vessel 1. Curve E corresponds to a temperature measurement at a distance of 5 cm above the bottom of the vessel 1. Curve F corresponds to a temperature measurement measured at the bottom of the vessel 1.

Advantageously, a transfer of heat takes place by convection between the hot air contained in the enclosure 2 and the vessel 1 and the distribution means 13 and 14 when the second heating means 20 is being used. However, natural convection may not be enough on its own to supply the energy necessary to ensure the desired gas phase flow rates on an industrial scale, notably for chemical vapor deposition applications where the deposition rates desired are increasingly high.

The first, second and/or third heating means may heat the vessel 1 such that the vapor pressure of the precursor increases. The second means is used notably to generate the temperature profile. The third means can be used to adjust this profile. The first, second and/or third heating means act as additional means for adapting the temperature profile to the use conditions as effectively as possible.

The heating means which predominates in the supply of heat necessary in order for the desired pressure to be achieved and for the desired precursor flow rate to be ensured may be dependent on the use conditions of the device. In particular, this may be dependent on the fill level of the vessel 1 and on the contact surface between the precursor and the surrounding volume. When the vessel 1 is full, the first heating means and the second heating means have the greatest influence. When the vessel 1 is relatively sparsely filled, or even almost empty, the third heating means has the greatest influence in the heating of the precursor.

The heated solid precursor 11 is sublimed by using the available energy provided by the different heating means to the vessel 1. The distribution flow rate of the pure precursor is conditioned by its rate of sublimation. The higher the demanded withdrawal flow rate, the greater the energy demand and the more the vessel has to be heated. The same is true when an increase in the pressure of the fluid distributed by the vessel is desired due to a higher pressure demanded at the point of use. In both cases, it is necessary to increase the heat transferred by the first heating means. Moreover, if the consumption flow rate of the precursor vapors decreases at the point of use, it is also necessary to reduce the heating of the vessel 1 in order to reduce the quantity of gas phase 12 sublimed.

According to an advantageous embodiment, such as depicted in FIG. 1, the first heating means 10 are configured to deliver a variable heating power. Typically, the heating means 10 are connected to an electrical power supply member and the heating power varies as a function of the intensity of the supply current applied to the first heating means 10. The device further comprises at least one pressure sensor PC configured to measure the pressure inside the vessel 1. The pressure sensor PC is fluidically connected to the internal volume of the vessel 1. The pressure sensor PC may be mounted at the distribution means 13, 14, preferably downstream of the outlet of a valve 14 controlling the distribution of the gas phase 12, said valve being arranged downstream of the outlet 17, or between the outlet 17 of the vessel 1 and the valve 14 or directly on the vessel 1. The pressure sensor may also be situated outside the enclosure and be fluidically connected to the vessel 1. A control unit 40 is connected to the pressure sensor PC and to the first heating means 10. The control unit 40 is configured to vary the heating power delivered by the first heating means 10 as a function of the pressure measured by the pressure sensor PC.

Note that, at the same time, the second heating means advantageously continues to heat the internal volume of the enclosure 2 and the vessel 1.

The heating power is thus adapted to adapt the temperature to which the precursor is heated in the vessel 1 in order to stabilize the pressure in the vessel 1. In the event of variation, the control unit adapts the heating conditions by way of the first means 10 so as to adjust the pressure in the vessel. A continuous distribution with a stable gas phase flow rate is thus ensured. This mode of regulation is more effective and safer than an independent regulation of the first heating means, since a variation in pressure has a direct and immediate impact on the state of the physical system in the vessel 1.

This embodiment is suitable for the case where the precursor is distributed in pure form, since the pressure in the vessel 1 corresponds to the pressure of the gas phase 12 and directly reflects the quantity of precursor that can be sublimed.

Preferably, the control unit 40 is configured to compare the pressure measured inside the vessel 1 with a setpoint pressure. The heating power is increased when the pressure measured inside the vessel 1 is lower than the setpoint pressure. The heating power is reduced when the pressure measured inside the vessel 1 is greater than or equal to the setpoint pressure. Note that the reduction in the heating power is understood to mean heating with a lower power or stoppage of the heating, as a function of the pressure difference calculated by the control unit 40 between the pressure setpoint and the measured pressure of the system.

The setpoint pressure may be predefined as a function notably of the operating conditions of the installation, of the components of the installation, of the pressure and of the flow rate demanded at the point of use and/or of the nature of the precursor, each precursor molecule having a specific curve of variation of its saturation vapor pressure as a function of the temperature. Preferably, the setpoint pressure is defined and the first heating means 10 are configured such that, when they operate at what is referred to as a nominal power, the precursor is heated to a temperature at which its saturation vapor pressure is equal to the setpoint pressure. The greater the difference between the setpoint pressure and the pressure measured in the vessel 1, the more the power of the first heating means is increased with respect to the nominal power.

Optionally, the control unit 40 may also be configured to compare the pressure measured inside the vessel 1 with a high pressure threshold. Note that the device may comprise a venting line with a vent associated with a valve or a vacuum network 61 fluidically connected to the vessel 1, and at least one valve controlling the passage of fluid to the vacuum network. If the pressure measured by the pressure sensor PC is greater than the high pressure threshold, the control unit 40 commands the opening of this valve, thus making it possible to reduce the pressure in the vessel 1 more rapidly and to provide additional safety. FIG. 4 shows an exemplary embodiment in which the pressure is released by virtue of a three-way valve connected to a vacuum line 61.

Potentially, the device may comprise a purging duct 63 fluidically connected to the vessel 1 and to the distribution means 13, 14 so as to convey a purging gas therein. This makes it possible, during start-up or maintenance phases, to purge the pipes of the device and the vessel 1.

The regulation of the heating of the vessel 1 as a function of the pressure also makes it possible to adapt the temperature to which the vessel 1 is heated as a function of the gas phase flow rate demanded at the point of use 60. Typically, if the flow rate demanded at the point of consumption increases, this results in a decrease in the pressure measured by the sensor PC because there is not enough sublimed precursor. In response, the control unit 40 commands an increase in the heating power in order to increase the saturation vapor pressure and to sublime more precursor. If the flow rate and/or pressure demanded at the point of consumption decreases, this results in an increase in the pressure measured by the sensor PC due to the excess of sublimed precursor. In response, the control unit 40 commands a decrease in the heating power in order to sublime less precursor and/or the opening of the valve leading to the vacuum network 61 if the high pressure threshold is exceeded.

Advantageously, the device according to the invention implements a first feedback control loop for controlling the power of the first heating means 10 on the basis of the pressure measured by the sensor PC. The term “feedback control loop” is generally understood to mean a system for controlling a process in which a regulating quantity acts on a regulated quantity, i.e. a quantity to be feedback-controlled, in order to bring it as quickly as possible to a setpoint value and maintain it thereat. The basic principle of feedback control is to measure, continuously, the difference between the actual value of the quantity to be feedback-controlled and the setpoint value that it is desired to achieve, and to calculate the appropriate command to apply to one or more actuators so as to reduce this difference as quickly as possible. It is also referred to as a closed-loop controlled system.

In the feedback control loop, the regulating quantity is the pressure measured by the sensor PC, the regulated quantity is the heating power of the vessel 1, and therefore indirectly the heating temperature of the solid phase 11, via the setting of the power of the first heating means 10.

Besides the sensor PC, the feedback control loop comprises a comparator arranged within the control unit 40 and configured to produce at least one error signal from the comparison between the measured pressure and the setpoint pressure. The loop comprises a corrector configured to produce the control signal from the error signal. The corrector sends the control signal to the unit 40 which commands the adjustment of the heating power. Preferably, the corrector is of the proportional, integral and derivative (PID) type, thus making it possible to improve the performance of a feedback owing to three combined actions: a proportional action, an integral action, a derivative action. The proportional, integral and derivative terms can be determined by calculation and/or experimentally. The derivative term of D may potentially be zero.

Advantageously, the control unit 40 comprises a programmable controller, also referred to as a PLC (Programmable Logic Controller) system, i.e. a control system for an industrial process comprising a human-machine interface for supervision and a digital communication network. The PLC system may comprise several modular controllers which control the sub-systems or equipment for controlling the device. These items of equipment are each configured to ensure at least one operation from among: acquisition of data from at least one measurement sensor, control of at least one actuator connected to at least one flow rate or pressure control member, regulation and feedback of parameters, transmission of data between the various items of equipment of the system.

The control unit 40 may thus comprise at least one from among: a microcontroller, a microprocessor, a computer. The control unit 40 may be connected to the various items of equipment for controlling the device, notably to the members for regulating the flow rate and the pressure, to the sensors, to the members for controlling the heating means, and communicate with said items of equipment by electrical, Ethernet, Modbus, etc. connections. Other modes of connections and/or transmission of information are conceivable for all or some of the equipment of the device, for example by radiofrequency, WIFI, Bluetooth, etc. connections.

Note that the term “control unit” covers one and the same unit controlling the different heating means or several control members which can independently control all or some of the heating means.

According to one implementation possibility, the control unit 40 comprises a human-machine interface comprising an input interface, for example a touchscreen, which allows a user to input instructions for the control unit 40 and/or data relating notably to the nature of the precursor, to the flow rate and/or to the desired distribution pressure, to the treatment installation, etc.

FIG. 2 illustrates one embodiment in which the device is intended to distribute a gas phase 12 diluted in a carrier gas 4. Note that all or some of the features described above can be applied to the case of the distribution of the diluted gas phase, notably the features relating to the control unit, to the regulation loop, to the enclosure, to the second heating means, etc.

A source of carrier gas 4 is connected by a supply duct 15 to an inlet 16 of the vessel 1. The source of carrier gas 4 may be a container in which the carrier gas can be stored in the gas state, in the liquid state, i.e. liquefied gas, or in a liquid/gas biphasic state, such as a gas cylinder, a set of cylinders that are connected to one another so as to form a bundle of cylinders or a tank of greater capacity, such as a cryogenic storage tank.

The device comprises means 41, 42 for circulating the carrier gas that are configured to circulate the carrier gas 4 between the inlet 16 and the outlet 17 of the vessel 1 such that the carrier gas 4 is charged into the gas phase 12 when it circulates in the vessel 1. A mixture of precursor and of carrier gas is thus distributed to the point of use.

The device according to the invention may notably be used to produce mixtures of precursor vapors and of carrier gas that have precursor contents of between 1 ppmm and 10%, preferably between 50 ppmm and 5% (ppm and % by mass), the balance being the carrier gas. For example, mixtures having the following compositions may be distributed: 1700 ppm of WCl₅ in N₂, 3.5% of WCl₆ in N₂.

In order to adapt to the pressure and/or to the flow rate demanded at the point of use 60, the means 41, 42 for circulating the carrier gas are configured to regulate the flow rate of carrier gas 4 sent to the vessel 1 and/or to regulate the pressure in the vessel 1. Depending on the case, the means 41, 42 for circulating the carrier gas may comprise at least one from among: an upstream flow rate regulator 41 arranged upstream of the vessel 1 so as to regulate the flow rate of the carrier gas 4 flowing to the vessel 1, an upstream pressure regulator 41 arranged upstream of the vessel 1 so as to regulate the pressure in the vessel 1, a downstream flow rate regulator 42 arranged downstream of the vessel 1 so as to regulate the flow rate of the gas mixture flowing from the vessel 1, a downstream pressure regulator 42 arranged downstream of the vessel 1 making it possible to regulate the pressure in the vessel 1. The pressure regulator 42 may be a flow rate controller (used to control the pressure), a backpressure regulator, a butterfly valve, etc.

In particular, the supply duct 15 may be provided with an expansion device 41 and/or the distribution duct 13 may be provided with a backpressure regulator 42 in order to regulate the pressure in the vessel 1. The backpressure regulator 42 functions as an upstream pressure regulator, that is to say that it is configured to regulate the pressure of the fluid in the gas circuit upstream of the backpressure regulator 42. The use of the backpressure regulator 42 makes it possible to keep the upstream pressure constant, while the downstream pressure may fluctuate. According to one embodiment, the backpressure regulator may comprise a chamber mounted in bypass, a valve operated by a control membrane. This membrane is balanced on the one hand by a weighted spring provided to close and open a duct connected to the gas circuit and on the other hand by the pressure to be stabilized upstream. The pressure in the vessel can for example be kept constant, in particular at a value of between 67 mbara and 2 bara (bar absolute).

In particular, the device may comprise at least one expansion device 41 which functions as a downstream pressure reducer. The expansion device 41 is configured to regulate the pressure of the distributed mixture and ensures the stability of the pressure at the point of use of the mixture in order to meet the requirements of the treatment installation in terms of the accuracy and stability of the parameters of the mixture. In particular, the expansion device 41 may be mounted in series on the duct 15.

In particular, the supply duct 15 may be provided with a flow rate regulator 41 and/or the distribution duct 13 may be provided with a flow rate regulator 42 in order to regulate the flow rate of carrier gas 4 passing through the vessel 1. Each flow rate regulator member 41, 42 may be any means configured to set, regulate, adjust the flow rate of a fluid in order to bring it to a flow rate value closest to the desired value. Typically, the flow rate regulator members 41, 42 each comprise a flowmeter, associated with an expansion member, such as a valve, for example a proportional control valve. The valve comprises a moving part, typically at least one closure member, which is placed in the flow of fluid and the movement of which makes it possible to vary the passage cross section, and thus to vary the flow rate in order to bring it to the setpoint value.

As dilution of the precursor 12 in the carrier gas 4 is effected, the concentration of the gas phase of the precursor in the carrier gas is determined by the relationship between the flow rate of sublimed precursor and the flow rate of carrier gas. The stability of the concentration of the gas phase of the precursor in the carrier gas is ensured by the saturation of the carrier gas in the vessel 1 and by the stability of the temperature of the vessel 1. The stability of the flow rate of mixture distributed to the point of use is thus ensured by the stability of the flow rate of carrier gas circulating in the vessel 1.

The control unit 40 may thus be connected to the regulator members described above so as to control their operation, in particular so as to adjust the setpoint values that are applied to said members in order to bring them to values determined as a function of operating conditions of the installation.

As can be seen in FIG. 2, the device advantageously comprises at least one temperature sensor TC configured to measure the temperature of an outer surface of the vessel 1. The sensor TC may be any sensor configured to carry out temperature measurements by contact, in particular a resistance temperature sensor, for example a PT100 platinum resistance sensor, or a thermocouple or thermistor temperature probe.

Preferably, the temperature sensor TC is configured to measure the temperature of at least a portion of the outer surface of a wall of the vessel 1, preferably the peripheral wall situated between the bottom and the top. Preferably, the sensor TC is arranged at a height of the vessel at which the first heating means 10 extends. This provides greater regulation accuracy and speed.

The control unit 40 is connected to the temperature sensor TC and to the first heating means 10, the control unit 40 being configured to vary the heating power delivered by the first heating means 10 as a function of the temperature measured by the temperature sensor TC.

Advantageously, the control unit 40 comprises means for comparing the temperature measured by the sensor TC with a third temperature setpoint of a predetermined value. The control unit 40 is configured to reduce the heating power when the temperature measured is greater than the third temperature setpoint and to increase the heating power when the temperature measured is lower than the third temperature setpoint. Note that the reduction in the heating power is understood to mean heating with a lower power or stoppage of the heating, as a function of the temperature difference calculated by the control unit 40 between the third temperature setpoint and the measured temperature.

The temperature to which the vessel 1 is heated is stabilized at its setpoint value. A continuous distribution with a stable gas phase flow rate is thus ensured. This embodiment is suitable for the case where the precursor is distributed in diluted form since, in this case, the pressure in the vessel 1 is dependent on the pressure of the carrier gas 4 and the temperature of the precursor.

The third temperature setpoint may be defined as a function notably of the operating conditions and of the components of the installation, of the pressure, of the flow rate demanded at the point of use and/or of the nature of the precursor. Preferably, the first heating means 10 are configured such that, when they operate at what is referred to as a nominal power, the surface temperature of the vessel measured by the sensor TC is equal to the third temperature setpoint. The third setpoint is determined in such a way that the precursor vapor concentration in the carrier gas meets the specifications of the treatment installation. If the treatment installation requires a greater concentration of precursor, the third temperature setpoint will be increased in order to increase the saturation vapor pressure of the precursor. If the treatment installation requires a lower concentration of precursor, the setpoint will be reduced in order to decrease the saturation vapor pressure of the precursor.

Note that the device according to the invention may comprise both a pressure sensor PC and a temperature sensor TC as described above. This makes it possible, using one and the same device, to be able to regulate the heating power in a mode for distributing precursor in pure form or in a mode for distributing precursor in diluted form. Depending on the operating mode, the control unit 40 is configured to produce signals for controlling the heating power on the basis of measurements originating from one or other of the sensors.

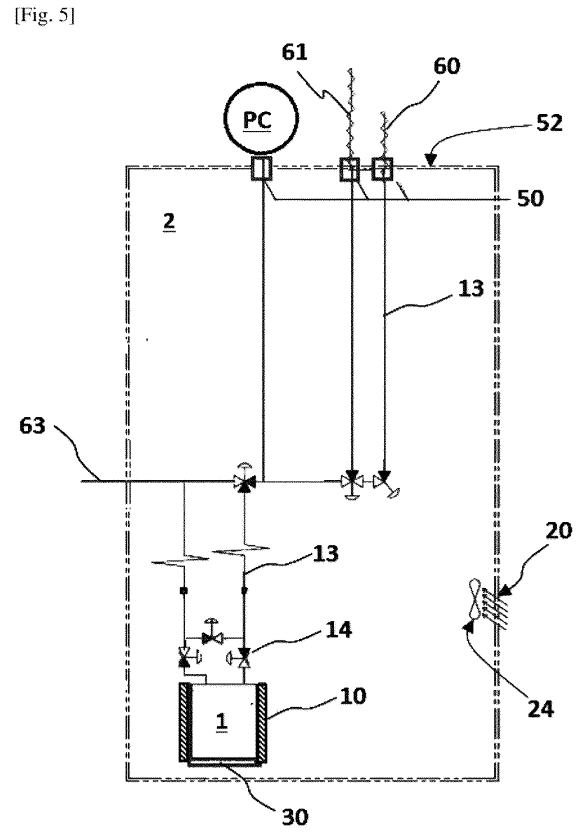

As can be seen in FIG. 5, the distribution means 13, 14 comprise at least one distribution duct 13 passing through a first wall 52 of the enclosure 2. The device may further comprise at least one heating element 50 forming a sleeve around at least a part of the distribution duct 13 and extending on either side of said first wall 52.

Specifically, since the walls of the enclosure are generally insulated in order to ensure thermal sealing, the wall passages can form cold points on the path of the gas phase 12, thus leading to a risk of recrystallization of the gas phase at the wall passages. In order to remedy this, one or more heating elements are inserted in the walls of the enclosure and the distribution duct is heated at its passage in the wall so as to avoid the recrystallization of the sublimed precursor and to maintain an increasing temperature in the axial direction z.

According to a particular embodiment, the heating element 50 may comprise two heating half-shells formed of a thermally conducting material. The half-shells may contain one or more heating cartridges and at least one temperature probe. The shells are inserted in the wall of the enclosure and are heated, preferably with a constant temperature.

As in the example of FIG. 5, it is also possible for a heating element 50 to be arranged around the vacuum line 61 and/or around a measurement line 62 for measuring pressure.

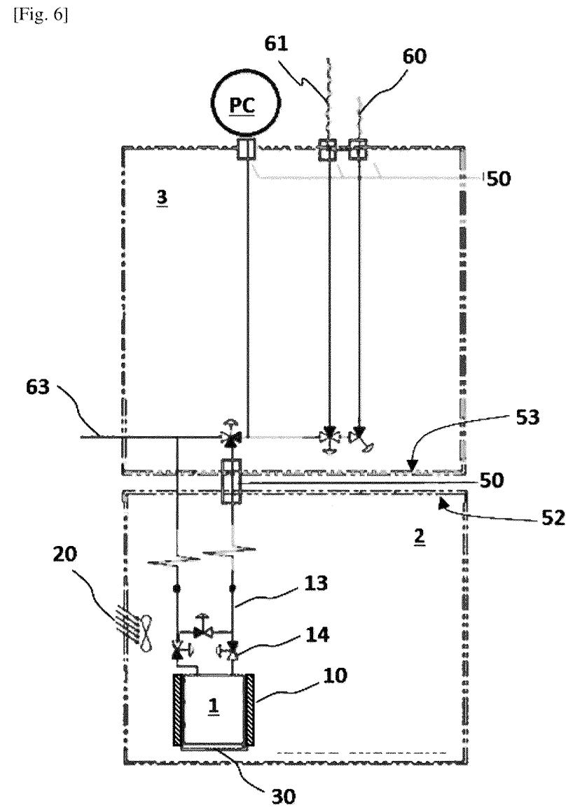

FIG. 6 depicts one embodiment in which the distribution device further comprises at least one additional enclosure 3 having a second wall 53 arranged facing the first wall 52 of the enclosure 2. The distribution duct 13 that conveys the precursor vapors from the vessel 1 passes through the second wall 53 of the additional enclosure 3 and distributes the vapors to the point of use 60. Note that the additional enclosure 3 is not necessarily positioned above the enclosure 2 but that other arrangements are possible, depending on the location of the point of use and the available footprint.

The additional enclosure 3 comprises third heating means configured to heat at least a part of the internal volume of the additional enclosure 3 to temperatures greater than the temperatures of the enclosure 2. An increase in the temperature in the axial direction z is thus complied with in order to avoid the recrystallization of the product in the lines of the enclosure 3. Preferably, a heating element 50 as described above is arranged around the distribution duct 13 at its passage through the second wall 53.

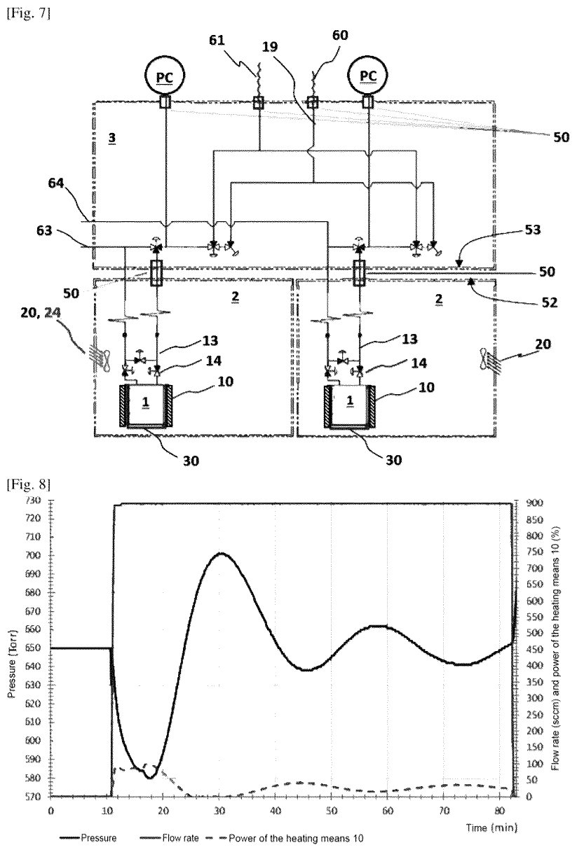

In one embodiment illustrated in FIG. 7, a distribution assembly is implemented with at least two distribution devices according to the invention arranged in parallel. More precisely, each device comprises a vessel 1 and respective distribution means 13, 14 fluidically connected to a common pipe 19, which is itself connected to the point of consumption 60. Note that the arrangement of an additional enclosure 3 is optional.

Advantageously, the assembly comprises switching means configured to occupy a first position in which the gas phase 12 is distributed into the common pipe 19 from one of the two vessels. The switching means may comprise the valves 14 of the respective distribution means 13, 14 and/or additional valves connected to the distribution means such as angled valves, as are visible in FIG. 7.

Preferably, the switching from one source to the other is effected automatically, that is to say without any intervention by an operator. When the quantity of precursor in the vessel 1 is lower than or equal to a predetermined low threshold, the switching means are moved to a second position in which the gas phase 12 is distributed into the common pipe 19 from the other of the two vessels 1. Preferably, the movement of the switching means from the first position to the second position is triggered on the basis of the measurement of a physical quantity representative of the quantity of precursor in the vessel 1, said physical quantity being able to be selected from among: the mass of the vessel 1, the pressure in the vessel 1, the temperature of an outer surface of the vessel 1.

According to one possibility, the mass of the vessel 1 is measured, this amounting to measurement of the mass of precursor remaining in the vessel. Preferably, the gross mass of the vessel containing the precursor is measured. The net mass of precursor in the vessel 1 is deduced from prior knowledge of the mass of the empty vessel, which an operator can for example input into the control unit at the start of use of the vessel. Preferably, the device comprises means for weighing at least one vessel 1 in order to monitor the change in the mass of the vessel 1. When the mass of precursor becomes lower than a given threshold, this triggers the movement of the switching means.

According to another possibility, the pressure in the vessel 1 is measured. If the pressure becomes lower than a given threshold, this means that there is no longer enough solid phase in the vessel to maintain the pressure setpoint. This triggers the movement of the switching means.

According to another possibility, the temperature of an outer surface of the vessel 1, i.e. the skin temperature of the vessel 1, is measured. If the temperature exceeds a given threshold, this means that there is no longer enough precursor in the vessel and the temperature of the first heating means 10 is increased in order to maintain the pressure setpoint. This triggers the movement of the switching means.

The advantage of an assembly with several distribution devices is that of allowing continuous operation of the treatment installation that uses the precursor, in spite of the depletion of a vessel. Specifically, when the vessel being used reaches the low threshold, the other vessel can be used while the empty vessel is replaced with a new full vessel.

Potentially, the switching means may occupy an intermediate position in which the gas phase 12 is distributed from both vessels simultaneously, prior to the switching to the other vessel. This makes it possible to avoid pressure drops during the opening of the valves of the second vessel 1 and to completely empty the first vessel in order to increase the efficiency of use.

Preferably, the main enclosures 2 that make up the distribution assembly are arranged side-by-side and an additional enclosure 3 is arranged above the main enclosures 2. The internal volume of the additional enclosure 3 is heated to a temperature greater than the temperature to which the volume of the main enclosures 2 is heated, so as to always comply with the direction of variation of increasing temperature toward the top. Heating elements 50 are arranged at wall passages from each enclosure 2 to the additional enclosure 3.

Preferably, the device comprises at least one gas cabinet, in which one or more enclosures 2, 3 can be installed. The source of carrier gas may be situated in or outside of the cabinet as a function of the available space. Preferably, the control unit 40 can be arranged in or outside of the cabinet, either by being fixed to one of the walls of the cabinet, or positioned at a distance from the cabinet. A system of gas ducts is arranged in the cabinet. The cabinet may comprise means for controlling and/or maintaining the system of gas ducts such as valves, expansion devices, pressure measurement members, etc., making it possible to carry out operations such as distribution of gas, opening or closing of certain ducts or portions of ducts, management of the gas pressure, performing of purge cycles, leak tests, etc. The cabinet may comprise gas inlet openings for a supply with the carrier gas and a gas outlet opening for distributing the gas phase. The distribution duct 13 is connected to the outlet opening. In operation, the gas cabinet is connected to the treatment installation by the point of consumption 60. Other gas inlets may be provided, notably for a flushing gas, a calibration gas, etc.

### EXAMPLES

In order to demonstrate the effectiveness of a device according to the invention, MoO₂Cl₂ as pure precursor was distributed at a mass flow rate of 900 cm³/min standard (i.e. sccm standing for “standard cubic centimeters per minute”) and a pressure of 650 Torr. The setpoint pressure was 650 Torr. The first, second and third heating means 10, 20, 30 were implemented so as. The vessel 1 and the distribution means 13, 14 had a temperature profile as illustrated in FIG. 4.

FIG. 8 shows a change in flow rate at 11 min from 0 sccm to 900 sccm of MoO2Cl2. The precursor flowed for 71 min, then the flow was stopped. FIG. 8 also shows the pressure of the system and the power of the first heating means 10. It can be seen that, during the passage from 0 to 900 sccm, the pressure of the system decreases from 650 Torr (pressure setpoint) to 580 Torr. Owing to the decrease in pressure of the system, the power of the first heating means 10 increases from 2% to 100%. Due to the heating of the first heating means 10, the pressure of the system increases to 700 Torr. In view of the increase in pressure, the heating of the first heating means is decreased when the pressure increases again and approaches the setpoint pressure of 650 Torr and is stopped when the pressure exceeds the pressure setpoint. The pressure of the system then stabilizes around the pressure setpoint. It can be seen that the amplitude of the pressure oscillations decreases. The flow of precursor was stopped before the pressure of the system had stabilized, but a pressure variation of 1.5% was achieved in 71 min.

The device according to the invention can be used to distribute precursors used in different industries such as the semiconductor, photovoltaic, LED and flat screen industries or any other industry such as the mining, pharmaceutical, space or aeronautical industries.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

As used herein, the indefinite article “a” or “an” means one or more.

As used herein, “about” or “around” or “approximately” in the text or in a claim means±10% of the value stated.

“Comprising” in a claim is an open transitional term which means the subsequently identified claim elements are a nonexclusive listing i.e. anything else may be additionally included and remain within the scope of “comprising.” “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

All references identified herein are each hereby incorporated by reference into this application in their entireties, as well as for the specific information for which each is cited.

1-11. (canceled)

12. A device for distributing a gas phase of at least one solid precursor, said device comprising:
a vessel intended to contain a solid phase of said precursor, the vessel having a bottom and a top;
a first heating means configured to heat at least a part of the vessel and/or of the solid phase so as to form a gas phase of said precursor in the vessel;
distribution means fluidically connected to the vessel and configured to distribute the gas phase from the vessel to a point of use;
an enclosure having an internal volume in which the vessel, the first heating means and the distribution means are arranged, the enclosure having a substantially vertical axial direction (z) oriented in an upward direction, the internal volume of the enclosure comprising a lower zone and an upper zone; and
a second heating means configured to heat at least a part of the internal volume of the enclosure, the second heating means comprising an air circulation means configured to circulate air from the second heating means in the direction of the internal volume of the enclosure.

13. The device of claim 12, wherein the upper zone is arranged at a higher level than that of the lower zone in the axial direction (z), the first vessel and the first heating means being arranged in the lower zone and the second heating means and the distribution means being arranged in the upper zone.

14. The device of claim 12, further comprising a third heating means arranged in the lower zone of the enclosure, preferably around at least a part of the bottom of the vessel or under the bottom of the vessel.

15. The device of claim 12, wherein the second heating means comprises at least one electrical resistor notably mounted on a wall of the enclosure or in the vicinity of said wall.

16. The device of claim 12, further comprising at least one pressure sensor (PC) configured to measure the pressure inside the vessel, and a control unit connected to the pressure sensor (PC) and to the first heating means, the control unit notably being configured to regulate and/or adjust the heating power delivered by the first heating means as a function of the pressure measured by the pressure sensor (PC).

17. The device of claim 12, further comprising a source of carrier gas, a supply duct fluidically connecting the source of carrier gas to an inlet of the vessel and means for circulating the carrier gas in the vessel, said means for circulating the carrier gas being configured to circulate the carrier gas between the inlet and an outlet of the vessel such that the distribution means distribute a gas mixture comprising the gas phase and the carrier gas from the vessel, said means for circulating the carrier gas notably being configured to control the flow rate of carrier gas circulating in the vessel and/or to control the pressure in the vessel.

18. The device of claim 12, further comprising at least one temperature sensor (TC) configured to measure the temperature of an outer surface of the vessel and/or to measure the temperature inside the enclosure, and a control unit connected to the temperature sensor (TC) and to the first heating means, the control unit notably being configured to vary the heating power delivered by the first heating means as a function of the temperature measured by the temperature sensor (TC).

19. The device of claim 12, wherein the distribution means comprise at least one distribution duct passing through a first wall of the enclosure, a heating element forming a sleeve around at least a part of the distribution duct and extending on either side of said first wall.

20. A distribution assembly comprising at least two distribution devices as defined by claim 12, each device comprising an enclosure, a vessel and respective distribution means fluidically connected to a common pipe, said assembly comprising switching means configured to occupy a first position in which the gas phase is distributed into the common pipe from one of the two vessels and, when the quantity of precursor in the vessel is lower than or equal to a predetermined low threshold, to occupy a second position in which the gas phase is distributed into the common pipe from the other of the two vessels or to occupy an intermediate position in which the gas phase is distributed from both vessels simultaneously, the switching means being connected to a member for measuring a physical quantity representative of the quantity of precursor in the vessel, selected from among: the mass of the vessel, the pressure in the vessel, the temperature of an outer surface of the vessel, the movement of the switching means from the first position to the second position being determined as a function of the measurement of said physical quantity.

21. A treatment installation or a chemical vapor deposition installation, comprising a treatment chamber in which one or more substrates to be treated are installed, the treatment chamber comprising means for introducing at least one gas phase of a solid precursor into the treatment chamber, wherein the introduction means are fluidically connected to the distribution means of a device as defined by claim 12 or of an assembly as defined by claim 20.

22. A method for distributing a gas phase of at least one solid precursor, comprising the following steps:
a) arranging a solid phase of said precursor in a vessel;
b) heating at least a part of the vessel and/or of the solid phase with a first heating means so as to form a gas phase of said precursor in the vessel;
c) distributing the gas phase from the vessel by way of distribution means that are fluidically connected to the vessel;
d) arranging the vessel, the first heating means and the distribution means in an internal volume of an enclosure, the enclosure having a substantially vertical axial direction (z) oriented in an upward direction, the internal volume of the enclosure comprising a lower zone and an upper zone; and
e) heating at least a part of the internal volume of the enclosure with a second heating means, the second heating means comprising an air circulation means configured to circulate air from the second heating means in the direction of the internal volume of the enclosure.
